(19) United States
(12) Patent Application Publication
(10) Pub. No.: US 2010/0096178 A1
(43) Pub. Date: Apr. 22, 2010

(54) NON-SHIRINKAGE CERAMIC SUBSTRATE AND MANUFACTURING METHOD THEREOF

(75) Inventors: Jin Waun KIM, Hwaseong (KR); Seung Gyo Jeong, Hwaseong (KR)

Correspondence Address: MCDERMOTT WILL & EMERY LLP, 600 13TH STREET, N.W., WASHINGTON, DC, 20005-3096, US

(73) Assignee: SUMSUNG ELECTRO-MECHANICS CO., LTD.

(21) Appl. No.: 12/478,524

(22) Filed: Jun. 4, 2009

(30) Foreign Application Priority Data
Oct. 17, 2008 (KR) 10-2008-0101935
Oct. 17, 2008 (KR) 10-2008-0101936

(51) Int. Cl. H05K 1/11; H05K 3/42

(52) U.S. Cl. 174/264; 29/851

(57) ABSTRACT

A non-shrinkage ceramic substrate includes: a ceramic laminated body formed by laminating a plurality of green sheets; an electrode part including a via electrode penetratingly formed at the ceramic laminated body and an outer electrode formed on a surface of the ceramic laminated body and electrically connected with the via electrode; and an interface part formed between the ceramic laminated body and the electrode part to prevent an electrical connection between the electrodes from weakening.

### CROSS-REFERENCE TO RELATED APPLICATIONS

This application claims the priority of Korean Patent Application Nos. 2008-0101935 and 2008-0101936 filed on Oct. 17, 2008, in the Korean Intellectual Property Office, the disclosure of which is incorporated herein by reference.

### BACKGROUND OF THE INVENTION

1. Field of the Invention

The present invention relates to a non-shrinkage ceramic substrate and its manufacturing method, and more particularly, to a non-shrinkage ceramic substrate including a barrier part or an interface spreading part formed at a ceramic laminated body and a method for manufacturing the non-shrinkage ceramic substrate.

2. Description of the Related Art

Recently, as the miniaturization trend is steadily strengthened in an electronic component line, a compact module and substrate are under development through miniaturization (precision) of electronic components, micro-patterning and film-thinning.

However, the use of a commonly used printed circuit board (PCB) for compact electronic components causes problems such as a reduction in size of the PCB, a signal loss in a radio frequency range, and degradation of reliability at a high temperature and high humidity.

To overcome such shortcomings, a ceramic substrate is in use in place of a PCB substrate. A main component of the ceramic substrate is a ceramic component containing a large quantity of glass available for low temperature co-firing.

The low temperature co-fired ceramic (multi-layered ceramic) substrate may be manufactured in various ways. Methods for manufacturing the low temperature co-fired ceramic may be classified into a shrinkage technology and a non-shrinkage technology depending on whether or not the ceramic substrate is shrunken when fired.

In detail, a method for manufacturing the ceramic substrate through shrinkage when the ceramic substrate is fired is the shrinkage technology. However, in the shrinkage technology, a shrinkage of the ceramic substrate does not occur uniformly overall, causing deformation of the dimension in a surface direction of the substrate.

The surface-directional shrinkage of the ceramic substrate causes deformation of the PCB included in the substrate, degrading precision of a pattern position, disconnection of the pattern, and the like.

Thus, as a solution to the problem of the shrinkage technology, a non-shrinkage technology has been proposed to prevent the surface-directional shrinkage of the ceramic substrate when it is fired.

The non-shrinkage technology is firing the ceramic substrate by forming restraining layers on both surfaces of the ceramic substrate. Due to the restraining layers, the ceramic substrate is not shrunken in the surface direction but shrunken in a thickness wise direction when fired.

In the ceramic substrate manufactured by the non-shrinkage technology, portions of ceramic green sheets constituting each layer are punctured to form a via hole. The via hole is filled with conductive paste to form a via electrode serving to electrically connect an internal electrode and an external electrode formed on the ceramic green sheets.

The via electrode, the internal electrode, and the ceramic green sheets are made of different components. Thus, in the process of sintering the ceramic substrate, the internal and external electrodes are first fired at a high firing temperature, according to which interface particles of the internal and external electrodes naturally move into the relatively porous via electrode.

Such movement causes a void, a crack, and the like, at the internal and external electrodes, or weakens the interface to weaken mutual electrode connectivity.

### SUMMARY OF THE INVENTION

An aspect of the present invention provides a non-shrinkage ceramic substrate and method for manufacturing the substrate capable of preventing an electrode connectivity from weakening due to a void generated at an inner electrode and an outer electrode and weakened interface.

According to an aspect of the present invention, there is provided a non-shrinkage ceramic substrate including: a ceramic laminated body formed by laminating a plurality of green sheets; an electrode part including a via electrode penetratingly formed in the ceramic laminated body and an outer electrode formed on a surface of the ceramic laminated body and electrically connected with the via electrode; and an interface part formed between the ceramic laminated body and the electrode part to prevent an electrical connection between the electrodes from weakening.

The interface part of the non-shrinkage ceramic substrate may include a barrier part for restraining a material movement at the interfaces of the ceramic laminated body and the electrodes when the ceramic laminated body is fired.

The barrier part of the non-shrinkage ceramic substrate may include an outer barrier layer formed between the outer electrode and the ceramic laminated body.

The outer barrier layer of the non-shrinkage ceramic substrate may be formed to entirely cover the surface of the via electrode.

The outer barrier layer of the non-shrinkage ceramic substrate may be formed to partially cover the surface of the via electrode.

The electrode part of the non-shrinkage ceramic substrate may further include an inner electrode formed at an inner side of the ceramic laminated body, and the barrier part may include an inner barrier layer formed between the inner electrode and the via electrode.

The inner barrier layer of the non-shrinkage ceramic substrate may be formed to entirely cover the surface of the via electrode.

The inner barrier layer of the non-shrinkage ceramic substrate may be formed to partially cover the surface of the via electrode.

The barrier part of the non-shrinkage ceramic substrate may include an electrode made of glass.

The interface part of the non-shrinkage ceramic substrate may include an interface spreading part comprising a spreading component spreading to the via electrode and the outer electrode when the ceramic laminated body is fired.

The interface spreading part of the non-shrinkage ceramic substrate may be made of a mixture of palladium (Pd) and silver (Ag).

The interface spreading part of the non-shrinkage ceramic substrate may be made of a mixture of platinum (Pt) and silver (Ag).

The interface spreading part of the non-shrinkage ceramic substrate may be formed to entirely cover the surface of the via electrode.

The interface spreading part of the non-shrinkage ceramic substrate may be formed to partially cover the surface of the via electrode.

The inner electrode of the non-shrinkage ceramic substrate may include an electrode made of a mixture of palladium (Pd) and silver (Ag).

The inner electrode of the non-shrinkage ceramic substrate may include an electrode made of a mixture of platinum (Pt) and silver (Ag).

According to another aspect of the present invention, there is provided a method for manufacturing a non-shrinkage ceramic substrate including: preparing a ceramic laminated body by laminating green sheets with a via electrode; forming an interface spreading part including a spreading component on a surface of the via electrode; and firing the ceramic laminated body.

In forming the interface spreading part on the surface of the via electrode, the interface spreading part may be formed to entirely cover the surface of the via electrode.

In forming the interface spreading part on the surface of the via electrode, the interface spreading part may be formed to partially cover the surface of the via electrode.

According to still another aspect of the present invention, there is provided a method for manufacturing a non-shrinkage ceramic substrate, including: preparing a ceramic laminated body by laminating green sheets with a barrier part formed on a surface of a via electrode; forming an outer electrode at the ceramic laminated body such that the outer electrode is positioned at an upper portion of the barrier part; and firing the ceramic laminated body.

In forming the barrier part on the surface of the electrode part, the barrier part may be formed to entirely cover the surface of the electrode part.

In forming the barrier part on the surface of the electrode part, the barrier part may be formed to partially cover the surface of the electrode part.

In the present invention, because the barrier part prevents the movement of a liquid material at the interface between the ceramic laminated body and the electrodes of the electrode part, the electrode connectivity can be improved. And, when the ceramic laminated body is fired, material movement is partially made from the barrier part made of glass to the green sheets, making the electrode part dense, and shrinkage of the electrode part can be restrained by the barrier part.

Also, in the present invention, the interface spreading part prevents a liquid movement at the interface between the via electrode part and the inner electrode part, and because the spreading component of the interface spreading part spreads to the via electrode part, the electrode connectivity among the inner electrode part, the outer electrode part, and the via electrode part can be improved.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a sectional view illustrating a barrier part of a non-shrinkage ceramic substrate according to a first embodiment of the present invention;

FIG. 2 is a view illustrating a portion of an upper surface of the ceramic substrate of FIG. 1;

FIG. 3 is a sectional view illustrating the non-shrinkage ceramic substrate according to the first embodiment of the present invention;

FIG. 4 is a view illustrating the shape of an outer electrode of the non-shrinkage ceramic substrate of FIG. 3;

FIG. 5 is a sectional view illustrating a barrier part of a non-shrinkage ceramic substrate according to a second embodiment of the present invention;

FIG. 6 is a view illustrating the shape of the barrier part of the non-shrinkage ceramic substrate of FIG. 5;

FIG. 7 is a sectional view illustrating the non-shrinkage ceramic substrate according to the second embodiment of the present invention;

FIG. 8 is a view illustrating the barrier part of the non-shrinkage ceramic substrate of FIG. 7;

FIG. 9 is a sectional view illustrating a ceramic laminated body of a non-shrinkage ceramic substrate according to a third embodiment of the present invention;

FIG. 10 is a sectional view illustrating an interface spreading part formed on a surface of the ceramic laminated body of FIG. 9;

FIG. 11 is a view illustrating a portion of an upper surface of the ceramic substrate of FIG. 10;

FIG. 12 is a sectional view illustrating anon-shrinkage ceramic substrate according to the third embodiment of the present invention;

FIG. 13 is a view illustrating the shape of an outer electrode of the non-shrinkage ceramic substrate of FIG. 12;

FIG. 14 is a sectional view illustrating an interface spreading part of a non-shrinkage ceramic substrate according to a fourth embodiment of the present invention;

FIG. 15 is a view illustrating the shape of the interface spreading part of the non-shrinkage ceramic substrate of FIG. 14;

FIG. 16 is a sectional view illustrating the non-shrinkage ceramic substrate according to the fourth embodiment of the present invention; and

FIG. 17 is a view illustrating the interface spreading part of the non-shrinkage ceramic substrate of FIG. 16.

### DETAILED DESCRIPTION OF THE PREFERRED EMBODIMENT

Exemplary embodiments of the present invention will now be described in detail with reference to the accompanying drawings. The invention may however be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

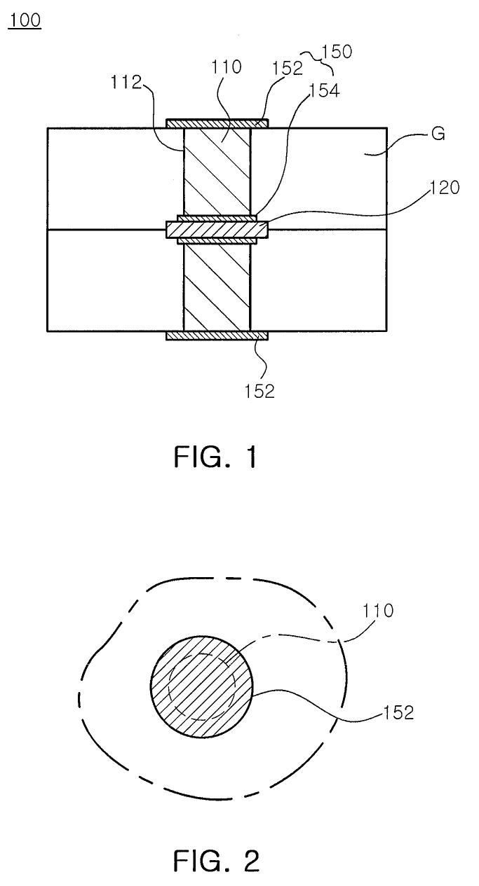

A non-shrinkage ceramic substrate and its manufacturing method according to embodiments of the present invention will now be described in detail with reference to FIGS. 1 to 8.

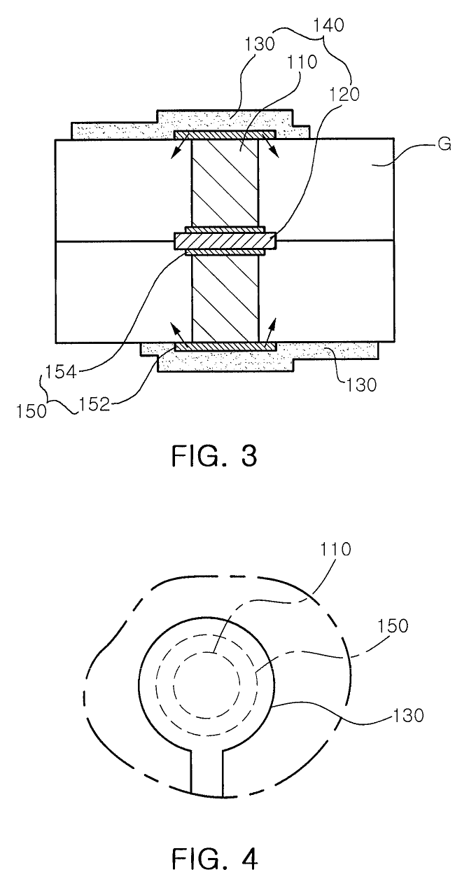

FIG. 1 is a sectional view illustrating a barrier part of a non-shrinkage ceramic substrate according to a first embodiment of the present invention. FIG. 2 is a view illustrating a portion of an upper surface of the ceramic substrate of FIG. 1. FIG. 3 is a sectional view illustrating the non-shrinkage ceramic substrate according to the first embodiment of the present invention. FIG. 4 is a view illustrating the shape of an outer electrode of the non-shrinkage ceramic substrate of FIG. 3.

With reference to FIGS. 1 to 4, the non-shrinkage ceramic substrate includes a ceramic laminated body 100, an electrode part 140, and a barrier part 150.

The ceramic laminated body 100 is formed by forming and laminating a plurality of ceramic green sheets (G). In detail, an organic binder, a dispersant, and a mixture solvent are added to glass-ceramic powder, which is then dispersed by using a ball mill.

The thusly obtained slurry is filtered out with a filter and defoamed, and then the ceramic green sheets of a certain thickness are molded by using a doctor blade method.

However, the method for molding the ceramic green sheets are not limited thereto and various other methods may be employed.

The electrode part 140 includes a via electrode 110, an inner electrode 120 and an outer electrode 130.

The via electrode 110 is formed such that it penetrates the ceramic laminated body 100, and serves to connect the inner electrode 120 and the outer electrodes 130.

In fabricating the ceramic green sheets, the via electrode 110 is formed such that a via hole 112 is formed at each ceramic green sheet and then filled with conductive paste therein.

Here, as the conductive paste, silver (Ag) with good electroconductivity may be used, but the conductive paste may not be limited to silver and may be made of various other materials such as nickel (Ni), plumbum (Pb), tungsten (W), tin (Sn), and the like.

The inner electrode 120 is formed between the ceramic green sheets (G), and electrically connected with the external electrode 130 via the via electrode 110.

As shown in FIG. 1, in firing the ceramic laminated body 100, when a firing temperature reaches, materials are bound to move at the interfaces of the green sheet (G) and the electrode part 140. The barrier part 150, including an outer barrier layer 152 and an inner barrier layer 154, restrains such material movement

The outer barrier layer 152 is formed to entirely cover a surface of the via electrode 110, and the outer electrode 130 is formed on the outer barrier layer 152.

The inner barrier layer 154 is formed between the via electrode 110 and the inner electrode 120.

As shown in FIG. 2, when viewed from the upper side of the ceramic laminated body 100, the barrier part 150 is preferably formed to have a circular shape corresponding to the circular via electrode 110, and completely covers the surface of the via electrode 110.

With reference to FIG. 3, the outer electrode 130 is formed by screen-printing the conductive paste on the surface of the ceramic laminated body 100, and preferably completely covers the via electrode 110 and the barrier part 150.

Also, as shown in FIG. 3, the barrier part 150 contains glass of a ceramic component, so the material of the barrier part 150 moves to the interior of the green sheets (G) or to the via electrode 110, attaining the effect of making the electrode part 140 compact and dense (as indicated by arrows in FIG. 3)

When the ceramic laminated body is sintered and shrunken, the barrier part 150 containing glass applies restraints to the surface of the via electrode 110, restraining the electrode part 140 from being shrunken, thus preventing the occurrence of a void or crack.

As shown in FIG. 4, the outer electrode 130 may have a circular shape to correspond to the shape of the circular via electrode 110 and the circular barrier part 150, and a portion of the outer electrode 130 extends long so as to be electrically connected with a neighbor electrode pattern. However, the shape of the outer electrode 130 is not limited thereto, and the outer electrode 130 maybe designed in various other shapes.

In general, when a firing temperature reaches in the process of sintering the ceramic laminated body 100, liquid materials naturally move from the outer electrode 130 and the inner electrode 120 to the relatively porous via electrode 110.

Then, the interfaces of the outer electrode 130 and the inner electrode 120 weaken due to the liquid movement, resultantly making the electrode connectivity weaken.

However, in the present invention, because the barrier part 150 is positioned in a solid form at the interfaces of the outer electrode 130 and the inner electrode 120, it restrains the movement of the liquid materials.

Accordingly, the interfaces of the outer electrode 130 and the inner electrode 120 can be prevented from weakening, and thus, the electrode connectivity can be improved.

A method for manufacturing a non-shrinkage ceramic substrate includes preparing the ceramic laminated body 100 by laminating the green sheets (G) with the electrode part 140 formed thereon.

Next, the barrier part 150 is formed on the surfaces of the ceramic laminated body 100 and the electrode part 140. In this case, the barrier part 150 is formed to completely cover the inner electrode 120.

And then, the ceramic laminated body 100 is fired to complete a non-shrinkage ceramic substrate.

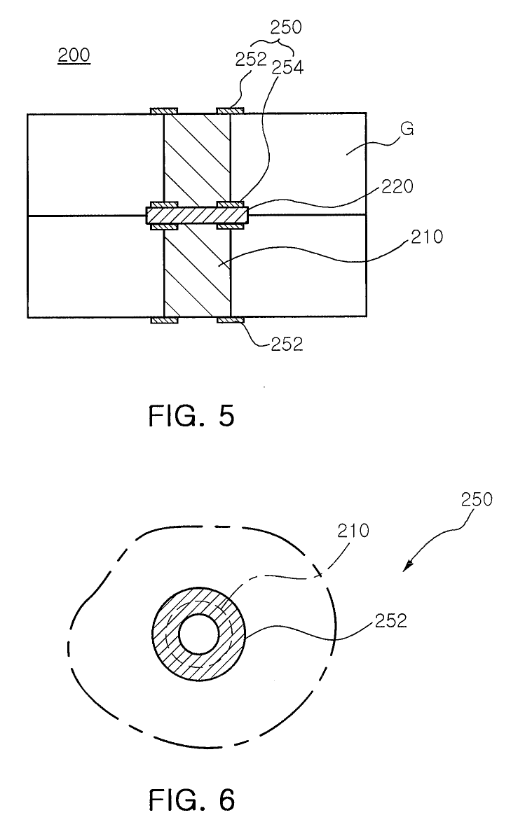

FIG. 5 is a sectional view illustrating a barrier part of a non-shrinkage ceramic substrate according to a second embodiment of the present invention, and FIG. 6 is a view illustrating the shape of the barrier part of the non-shrinkage ceramic substrate of FIG. 5.

With reference to FIGS. 5 and 6, the non-shrinkage ceramic substrate according to the second embodiment of the present invention includes a ceramic laminated body 200, an electrode part 240, and a barrier part 250.

The barrier part 250 includes an outer barrier layer 252 formed in a donut-like shape (i.e., ring shape) to partially cover a surface of a via electrode 210 formed in a circular shape, and an inner barrier layer 254 partially formed in the donut-like shape on a surface of an inner electrode 220.

Accordingly, because the central portion of the barrier part 250 is open to allow the via electrode 210 and the inner electrode 220 to be in direct contact with each other and electrically connected, their electrical connectivity can be further improved.

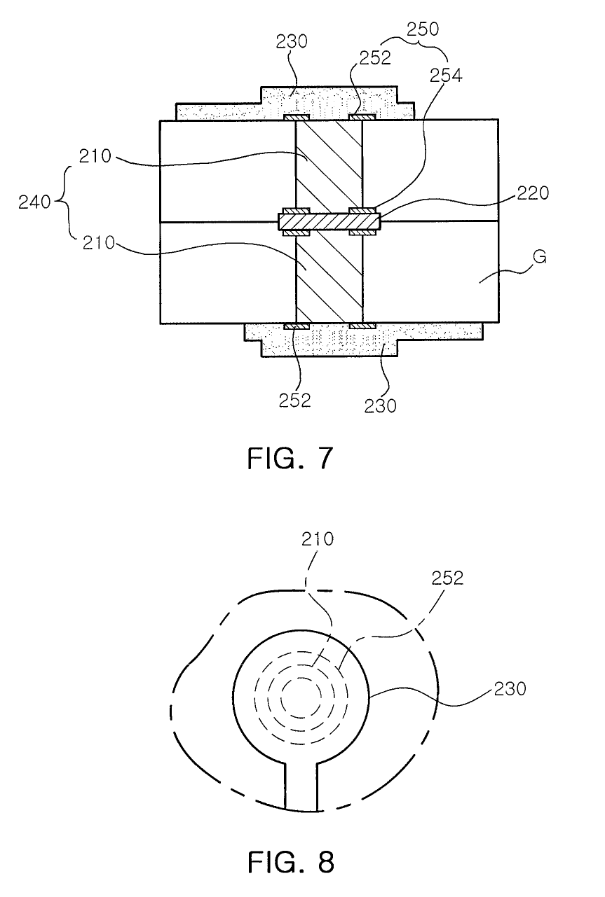

FIG. 7 is a sectional view illustrating the non-shrinkage ceramic substrate according to the second embodiment of the present invention, and FIG. 8 is a view illustrating the barrier part of the non-shrinkage ceramic substrate of FIG. 7.

An outer electrode 230 is formed by screen-printing conductive paste on the surface of the ceramic laminated body 200, and preferably, the outer electrode 230 is formed to completely cover the via electrode 210 and the barrier part 250.

In this case, the outer electrode 230 is formed in a circular shape corresponding to the shape of the surface of the via electrode 210 and the shape of the barrier part 250. However, the shape of the outer electrode 230 is not limited thereto, and the outer electrode 230 may be designed to have various other shapes.

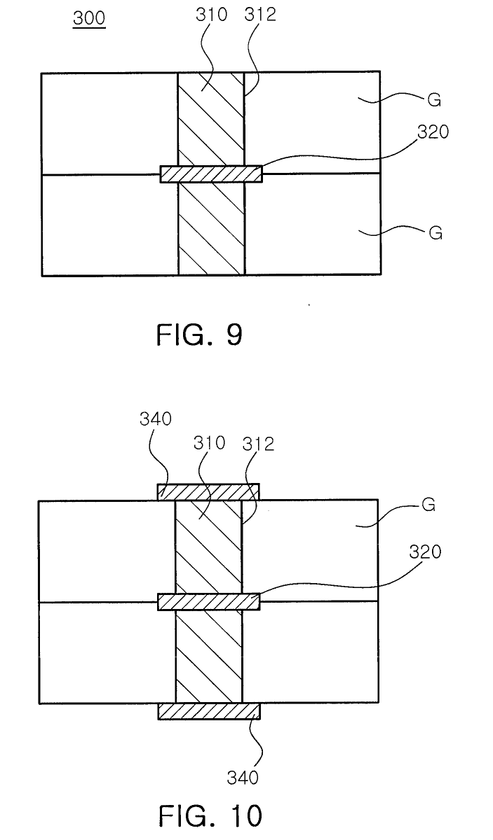

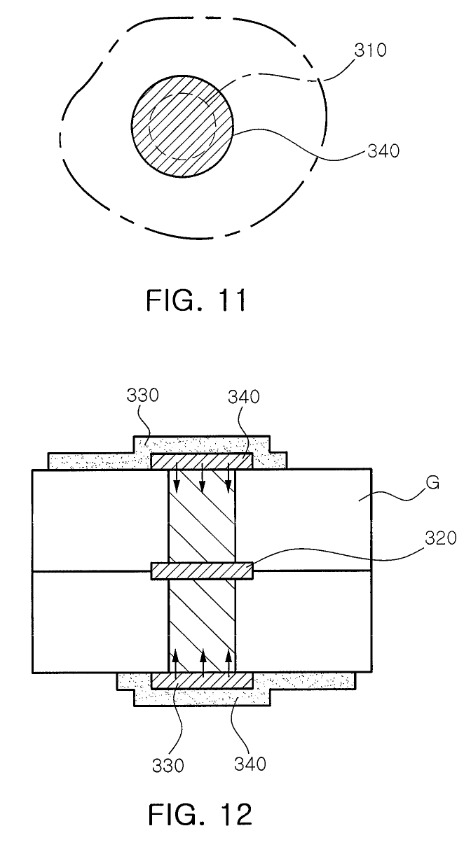

FIG. 9 is a sectional view illustrating a ceramic laminated body of a non-shrinkage ceramic substrate according to a third embodiment of the present invention, FIG. 10 is a sectional view illustrating an interface spreading part formed on a surface of the ceramic laminated body of FIG. 9, and FIG. 11 is a view illustrating a portion of an upper surface of the ceramic substrate of FIG. 10.

With reference to FIGS. 9 to 11, the non-shrinkage ceramic substrate includes a ceramic laminated body 300, a via electrode 310, an inner electrode 320, an outer electrode 330, and an interface spreading part 340.

The ceramic laminated body 300 is formed by forming and laminating a plurality of ceramic green sheets (G). In detail, an organic binder, a dispersant, and a mixture solvent are added to glass-ceramic powder, which is then dispersed by using a ball mill.

The thusly obtained slurry is filtered out with a filter and defoamed, and then the ceramic green sheets of a certain thickness are molded by using a doctor blade method.

The via electrode 310 is formed such that it penetrates the ceramic laminated body 300, and serves to connect the inner electrode 320 and the outer electrodes 330 (See FIG. 12).

In fabricating the ceramic green sheets, the via electrode 310 is formed such that a via hole 312 is formed at each ceramic green sheet and then filled with conductive paste therein.

Here, as the conductive paste, silver (Ag) with good electroconductivity may be used, but the conductive paste may not be limited to silver and may be made of various other materials such as nickel (Ni), plumbum (Pb), tungsten (W), tin (Sn), and the like.

The inner electrode 320 is formed between the ceramic green sheets, and electrically connected with the outer electrode 330 via the via electrode 310.

The inner electrode 320 may be made of a mixture of around 80% of silver (Ag) and around 20% of palladium (Pd).

However, the inner electrode 320 may not be limited to the mixture obtained by adding the certain amount of palladium (Pd), and may be made of a mixture of silver (Ag) and platinum (Pt), or 100% of palladium (Pt) and 100% of platinum (Pt).

Here, palladium (Pt) or platinum (Pt) has the characteristics of increasing a firing temperature of the inner electrode 320 and easily spreading to the via electrode 310 made of silver.

As shown in FIG. 10, the interface spreading part 340 is formed to entirely cover the surface of the via electrode 310.

As shown in FIG. 11, when viewed from the upper side of the ceramic laminated body 300, the interface spreading part 340 is formed to have a circular shape corresponding to the circular via electrode 310, to thus cover the via electrode 310.

Here, like the inner electrode 320, the interface spreading part 340 may be made of a mixture of around 80% of silver (Ag) and around 20% of palladium (Pd).

However, the interface spreading part 340 may not be limited to the mixture obtained by adding the certain amount of palladium (Pd), and may be made of a mixture of silver (Ag) and platinum (Pt), or a spreading component such as 100% of palladium (Pt) and 100% of platinum (Pt).

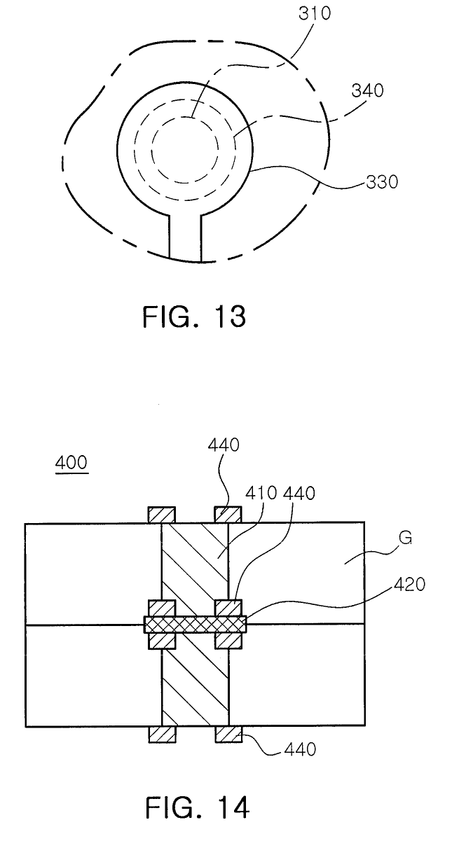

FIG. 12 is a sectional view illustrating a non-shrinkage ceramic substrate according to the third embodiment of the present invention, and FIG. 13 is a view illustrating the shape of the outer electrode of the non-shrinkage ceramic substrate of FIG. 12.

With reference to FIGS. 12 and 13, the outer electrode 330 is formed by screen-printing conductive paste on the surface of the ceramic laminated body 300, and preferably completely covers the via electrode 310 and the interface spreading part 340.

Here, as the conductive paste, silver (Ag) with good electroconductivity may be used, but the conductive paste may not be limited to silver and may be made of other materials such as nickel (Ni), plumbum (Pb), tungsten (W), tin (Sn), and the like.

As shown in FIG. 13, the outer electrode 330 may have a circular shape to correspond to the shape of the via electrode 310 and the interface spreading part 340, and a portion of the outer electrode 330 extends long so as to be electrically connected with a neighbor electrode pattern. However, the shape of the outer electrode 330 is not limited thereto. Namely, the outer electrode 330 may be designed in various other shapes.

In the related art, because the via electrode 310, the inner electrode 320, and the outer electrode 330 are made of different materials, when the ceramic substrate is fired, sintering first occurs at the interface of the inner electrode 320 and the outer electrode 330, and accordingly, interface particles constituting the inner electrode 320 and the outer electrode 330 move in a liquid phase to the interior of the relatively porous via electrode 310 (as indicated by arrows in FIG. 12).

Such movement causes a void at the interface of the inner electrode 320 and the outer electrode 330, weakening the interface, to degrade mutual electrode connectivity.

However, the non-shrinkage ceramic substrate according to the present invention includes the interface spreading part 340 containing a spreading component. That is, when sintering, the spreading component constituting the interface spreading part 340 first spreads to the via electrode 310 to fill the relatively porous via electrode 310.

Accordingly, the interface spreading part 340 prevents a movement of particles at the outer electrode 330, and improves the electrode connectivity among the inner electrode 320, the outer electrode 330, and the via electrode 310 by virtue of the spreading components such as palladium (Pd) and the platinum (Pt).

In addition, the spreading components such as palladium (Pd) and platinum (Pt) increase the sintering temperature of the inner electrode 320, reducing the movement of particles between the inner electrode 320 and the via electrode 310 in sintering, so a void generation and interface weakening can be prevented.

The method for manufacturing the non-shrinkage ceramic laminated body according to the present invention will now be described with reference to FIGS. 9 to 13. First, the ceramic laminated body 300 is formed by laminating the green sheets (G) including the via electrode 310.

Next, the interface spreading part 340 including the spreading components such as palladium (Pd) and platinum (Pt) is formed on the surface of the via electrode 310.

In this case, the inner electrode 320 may be formed to have the same spreading component, i.e., palladium (Pd) and platinum (Pt), as those of the interface spreading part 340. In this case, the spreading components such as palladium (Pd) and platinum (Pt) serve to increase the firing temperature of the inner electrode 320.

After the interface spreading part 340 is formed at the ceramic laminated body 300, the ceramic laminated body 300 is fired.

In forming the interface spreading part 340 on the surface of the via electrode 320, the interface spreading part 340 is formed to entirely cover the surface of the via electrode 310.

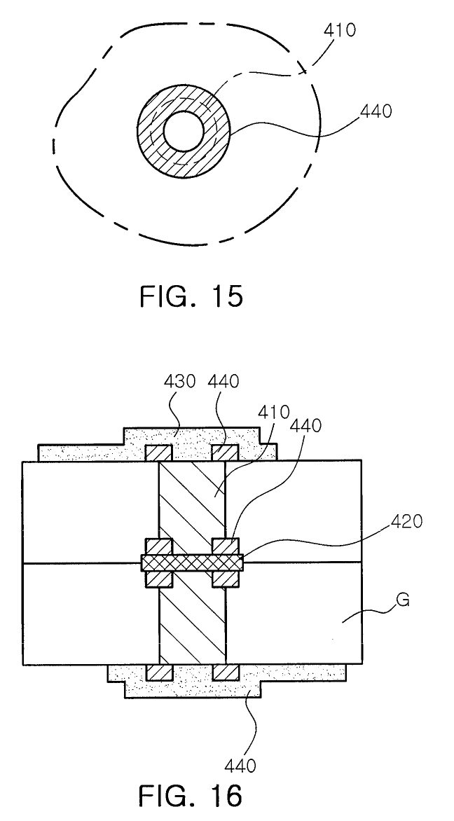

FIG. 14 is a sectional view illustrating an interface spreading part of a non-shrinkage ceramic substrate according to a fourth embodiment of the present invention, and FIG. 15 is a view illustrating the shape of the interface spreading part of the non-shrinkage ceramic substrate of FIG. 14.

With reference to FIGS. 14 and 15, an interface spreading part 440 is formed on a surface of a ceramic laminated body 400.

The interface spreading part 440 has a donut-like shape (i.e., ring shape) to partially cover a via electrode 410 formed in a circular shape. The interface spreading part 440 may be also formed on a surface of an inner electrode 420.

Accordingly, because the central portion of the interface spreading part 440 is open to allow the via electrode 410 and an outer electrode 430 to be in direct contact with each other and electrically connected, their electrical connectivity can be further improved.

Here, like the inner electrode 420, the interface spreading part 440 may be made of a mixture of around 80% of silver (Ag) and around 20% of palladium (Pd).

However, the interface spreading part 440 may not be limited to the mixture obtained by adding the certain amount of palladium (Pd), and may be made of a mixture of silver (Ag) and platinum (Pt), or 100% of palladium (Pt) and 100% of platinum (Pt).

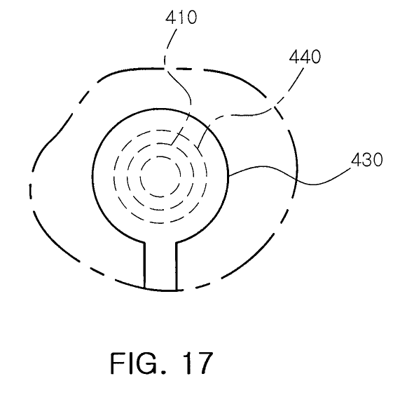

FIG. 16 is a sectional view illustrating the non-shrinkage ceramic substrate according to the fourth embodiment of the present invention, and FIG. 17 is a view illustrating the interface spreading part of the non-shrinkage ceramic substrate of FIG. 16.

The outer electrode 430 is formed by screen-printing conductive paste on the surface of the ceramic laminated body 400, and preferably completely covers the via electrode 410 and the interface spreading part 440.

Here, as the conductive paste, silver (Ag) with good electroconductivity may be used, but the conductive paste may not be limited to silver and may be made of other materials such as nickel (Ni), plumbum (Pb), tungsten (W), tin (Sn), and the like.

As shown in FIG. 17, the outer electrode 430 may have a circular shape to correspond to the shape of the via electrode 410 and the interface spreading part 440. However, the shape of the outer electrode 430 is not limited thereto. Namely, the outer electrode 430 may be designed in various other shapes.

While the present invention has been shown and described in connection with the exemplary embodiments, it will be apparent to those skilled in the art that modifications and variations can be made without departing from the spirit and scope of the invention as defined by the appended claims.

What is claimed is:

1. A non-shrinkage ceramic substrate comprising:
a ceramic laminated body formed by laminating a plurality of green sheets;
an electrode part comprising a via electrode penetratingly formed in the ceramic laminated body and an outer electrode formed on a surface of the ceramic laminated body and electrically connected with the via electrode; and
an interface part formed between the ceramic laminated body and the electrode part to prevent an electrical connection between the electrodes from weakening.

2. The substrate of claim 1, wherein the interface part comprises a barrier part for restraining a material movement at the interfaces of the ceramic laminated body and the electrodes when the ceramic laminated body is fired.

3. The substrate of claim 2, wherein the barrier part comprises an outer barrier layer formed between the outer electrode and the ceramic laminated body.

4. The substrate of claim 3, wherein the outer barrier layer is formed to entirely cover the surface of the via electrode.

5. The substrate of claim 3, wherein the outer barrier layer is formed to partially cover the surface of the via electrode.

6. The substrate of claim 1, wherein the electrode part further comprises an inner electrode formed at an inner side of the ceramic laminated body, and the barrier part comprises an inner barrier layer formed between the inner electrode and the via electrode.

7. The substrate of claim 6, wherein the inner barrier layer is formed to entirely cover the surface of the via electrode.

8. The substrate of claim 6, wherein the inner barrier layer is formed to partially cover the surface of the via electrode.

9. The substrate of claim 1, wherein the barrier part comprises glass.

10. The substrate of claim 1, wherein the interface part comprises:
an interface spreading part comprising a spreading component spreading to the via electrode and the outer electrode when the ceramic laminated body is fired.

11. The substrate of claim 10, wherein the interface spreading part is made of a mixture of palladium (Pd) and silver (Ag).

12. The substrate of claim 10, wherein the interface spreading part is made of a mixture of platinum (Pt) and silver (Ag).

13. The substrate of claim 10, wherein the interface spreading part is formed to entirely cover the surface of the via electrode.

14. The substrate of claim 10, wherein the interface spreading part is formed to correspond to the surface of the via electrode.

15. The substrate of claim 10, wherein the electrode part further comprises an inner electrode formed at an inner side of the ceramic laminated body, and the inner electrode comprises an electrode made of a mixture of palladium (Pd) and silver (Ag).

16. The substrate of claim 15, wherein the inner electrode comprises an electrode made of a mixture of platinum (Pt) and silver (Ag).

17. A method for manufacturing a non-shrinkage ceramic substrate, the method comprising:
preparing a ceramic laminated body by laminating green sheets with a barrier part formed on a surface of a via electrode;
forming an outer electrode at the ceramic laminated body such that the outer electrode is positioned at an upper portion of the barrier part; and
firing the ceramic laminated body.

18. The method of claim 17, wherein, in forming the barrier part on the surface of the electrode part, the barrier part is formed to entirely cover the surface of the electrode part.

19. The method of claim 17, wherein, in forming the barrier part on the surface of the electrode part, the barrier part is formed to entirely cover the surface of the electrode part.

20. A method for manufacturing a non-shrinkage ceramic substrate, the method comprising:
preparing a ceramic laminated body by laminating green sheets with a via electrode;
forming an interface spreading part containing a spreading component on a surface of the via electrode; and
firing the ceramic laminated body.

21. The method of claim 20, wherein, in forming the interface spreading part on the surface of the via electrode, the interface spreading part is formed to entirely cover the surface of the via electrode.

22. The method of claim 20, wherein, in forming the interface spreading part on the surface of the via electrode, the interface spreading part is formed to partially cover the surface of the via electrode.
